(19) United States
(12) Patent Application Publication
(10) Pub. No.: US 2025/0048835 A1
(43) Pub. Date: Feb. 6, 2025

(54) DISPLAY DEVICE

(71) Applicant: Samsung Display Co., Ltd., Yongin-si (KR)

(72) Inventors: JIHOON YANG, Yongin-si (KR); MIN KANG, Yongin-si (KR); JUNG SUK BANG, Yongin-si (KR); CHEOL-GON LEE, Yongin-si (KR)

(21) Appl. No.: 18/653,744

(22) Filed: May 2, 2024

(30) Foreign Application Priority Data
Aug. 1, 2023 (KR) 10-2023-0100364

(51) Int. Cl. H10K 59/121; H10K 59/131; H10K 59/65

(52) U.S. Cl. CPC H10K 59/1213; H10K 59/1216; H10K 59/131; H10K 59/65

(57) ABSTRACT

A display device includes a first control line, a second control line, and a third control line arranged in a first direction, the first control line being between the second control line and the third control line, a pixel circuit coupled to the first control line, the second control line, and the third control line, a light-emitting element coupled to the pixel circuit, a sensor circuit coupled to the first control line, and having a first connection node between the first control line and the third control line, a light-receiving element coupled to the sensor circuit, and a receive line coupled to the first connection node of the sensor circuit.

### CROSS-REFERENCE TO RELATED APPLICATIONS

The present application claims priority to, and the benefit of, Korean Patent Application No. 10-2023-0100364, filed on Aug. 1, 2023, in the Korean Intellectual Property Office, the entire disclosure of which is incorporated herein by reference.

### BACKGROUND

### 1. Field

Embodiments of the present disclosure described herein relate to a display device.

### 2. Description of the Related Art

An electronic device, such as a smart phone, a digital camera, a notebook computer, a navigation system, and a smart television, that provides an image to a user includes a display device to display the image. The display device includes a display panel to generate an image, an input device, such as an input sensor, a camera to capture an external image, and a various sensors.

The input sensor is located on the display panel to sense the touch of a user. The input sensor is manufactured using a separate panel, and is located on a display panel. The sensors may include a fingerprint sensor, a proximity sensor, and an illuminance sensor. The fingerprint sensor may sense a fingerprint provided on the display panel, may be manufactured using a separate module, and may be located in the display device.

### SUMMARY

Embodiments of the present disclosure provide a display device having a region improved or optimized to dispose a sensor circuit.

According to one or more embodiments, a display device may include a first control line, a second control line, and a third control line arranged in a first direction, the first control line being between the second control line and the third control line, a pixel circuit coupled to the first control line, the second control line, and the third control line, a light-emitting element coupled to the pixel circuit, a sensor circuit coupled to the first control line, and having a first connection node between the first control line and the third control line, a light-receiving element coupled to the sensor circuit, and a receive line coupled to the first connection node of the sensor circuit.

The display device may further include a data line coupled to the pixel circuit, a first initializing line coupled to the pixel circuit, and a second initializing line coupled to the pixel circuit and the sensor circuit, wherein the second initializing line is coupled to a second connection node and a third connection node of the sensor circuit.

The display device may further include a sensing-control line coupled to the sensor circuit, wherein the second control line is between the first control line and the sensing-control line.

The second connection node may be between the second control line and the sensing-control line.

The third connection node may be between the first control line and the second control line.

The sensor circuit may include a first transistor including a first electrode coupled to the second initializing line, a control electrode coupled to an anode of the light-receiving element, and a second electrode, a second transistor including a first electrode coupled to the second initializing line, a control electrode coupled to the sensing-control line, and a second electrode coupled to the anode, and a third transistor including a first electrode coupled to the second electrode of the first transistor, a control electrode coupled to the first control line, and a second electrode coupled to the receive line.

The first connection node may be defined as a connection point of the third transistor coupled to the receive line.

The second connection node may be defined as a connection point of the second transistor coupled to the second initializing line.

The third connection node may be defined as a connection point of the first transistor coupled to the second initializing line.

The second transistor may have a dual-gate structure, and the third transistor may have a dual-gate structure.

The first transistor, the second transistor, and the third transistor may include PMOS transistors.

The pixel circuit may include a first transistor including a first electrode coupled to a first power line, a second electrode coupled to an anode of the light-emitting element, and a control electrode coupled to a node, a second transistor including a first electrode coupled to the data line, a second electrode coupled to the first electrode of the first transistor, and a control electrode coupled to the first control line, and a capacitor including a first electrode coupled to the first power line, and a second electrode coupled to the node.

The pixel circuit may include a third transistor including a first electrode coupled to the second electrode of the first transistor, a second electrode coupled to the node, a control electrode coupled to the first control line, and a fourth transistor including a first electrode coupled to the node, a second electrode coupled to the first initializing line, and a control electrode coupled to the second control line.

The third transistor may have a dual gate structure, and the fourth transistor may have a dual-gate structure.

The pixel circuit may include a fifth transistor including a first electrode coupled to the first power line, a second electrode coupled to the first electrode of the first transistor, and a control electrode coupled to the third control line, and a sixth transistor including a first electrode coupled to the second electrode of the first transistor, a second electrode coupled to the anode, and a control electrode coupled to the third control line.

The display device may further include a fourth control line, and a bias line, wherein the pixel circuit includes a seventh transistor including a first electrode coupled to the anode, a second electrode coupled to the second initializing line, and a control electrode coupled to the fourth control line, and an eighth transistor including a first electrode coupled to the bias line, a second electrode coupled to the first electrode of the first transistor, and a control electrode coupled to the fourth control line.

The third control line may be between the first control line and the fourth control line.

The first to eighth transistors may include PMOS transistors.

According to one or more embodiments, a display device may include a first control line, a second control line, a third control line, and a sensing-control line arranged in a first direction, a pixel circuit coupled to the first control line, the second control line, and the third control line, a light-emitting element coupled to the pixel circuit, a sensor circuit coupled to the first control line and the sensing-control line, a light-receiving element coupled to the sensor circuit, a receive line coupled to a first connection node of the sensor circuit, a first initializing line coupled to the pixel circuit, and a second initializing line coupled to the pixel circuit, and to a second connection node and to a third connection node of the sensor circuit, wherein the first connection node, the second connection node, and the third connection node are between respective ones of the first control line, the second control line, the third control line, and the sensing-control line.

According to one or more embodiments, a display device may include a first control line, a second control line, and a sensing-control line arranged in a first direction, a pixel circuit coupled to the first control line and the second control line, a light-emitting element coupled to the pixel circuit, a sensor circuit coupled to the first control line and the sensing-control line, a light-receiving element coupled to the sensor circuit, and a first initializing line coupled to the pixel circuit, and a second initializing line coupled to the pixel circuit, and to two connection nodes of the sensor circuit that are respectively between the first control line, the second control line, and the sensing-control line.

### BRIEF DESCRIPTION OF THE DRAWINGS

The above and other objects and features of the present disclosure will become apparent by describing in detail embodiments thereof with reference to the accompanying drawings.

FIG. 1 is a perspective view illustrating a display device according to one or more embodiments of the present disclosure.

FIG. 2 is a cross-sectional view illustrating the display device illustrated in FIG. 1.

FIG. 3 is a cross-sectional view illustrating a display panel illustrated in FIG. 2.

FIG. 4 is a plan view of a display panel illustrated in FIG. 2.

FIG. 5 is a view illustrating an equivalent circuit of any one pixel of pixels illustrated in FIG. 4 and a sensor adjacent to the pixel.

FIG. 6 is a cross-sectional view illustrating a light-emitting element, a first transistor, and a second transistor of a pixel illustrated in FIG. 5.

FIG. 7 is a cross-sectional view illustrating a light-receiving element, a first transistor, and a second transistor of a sensor illustrated in FIG. 5.

FIG. 8 is a view illustrating an arrangement state of light-emitting elements and light-receiving elements located in a partial region of a display region illustrated in FIG. 4.

FIG. 9 is a view illustrating the sensing state of a fingerprint by sensors illustrated in FIGS. 5 and 7.

FIGS. 10A to 10F are views illustrating the structure of a pixel circuit and a sensor circuit illustrated in FIG. 5 when viewed in a plan view.

FIG. 11 is a view illustrating an edge of a display panel illustrated in FIG. 4 in more detail.

FIG. 12 is an enlarged view of region AA illustrated in FIG. 11 to describe the functions of horizontal data lines and vertical data lines illustrated in FIGS. 10E and 10F.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

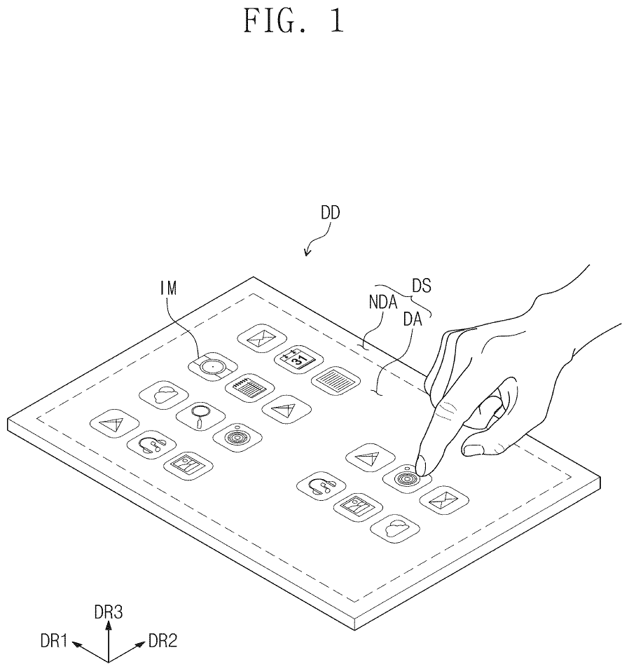

FIG. 1 is a perspective view of a display device according to one or more embodiments of the present disclosure.

Referring to FIG. 1, according to one or more embodiments of the present disclosure, a display device DD may have a shape of a rectangle having a longer side extending in a first direction DR1, and a shorter side extending in a second direction DR2 crossing the first direction DR1. However, one or more embodiments is not limited thereto, and the display device DD may have various shapes, such as a circle or a polygon.

Hereinafter, a direction substantially perpendicular to a plane defined by the first direction DR1 and the second direction DR2 is defined as a third direction DR3. Furthermore, in the specification, the meaning of “when viewed from above a plane” may mean “when viewed in the third direction DR3.”

A top surface of the display device DD may be defined as a display surface DS, and may have the plane defined by the first direction DR1 and the second direction DR2. Images IM generated by the display device DD may be provided to a user through the display surface DS.

The display surface DS may include a display region DA, and a non-display region NDA around the display region DA. The display region DA is to display an image, and the non-display region NDA is not to display the image. The non-display region NDA may be defined as an edge of the display device DD to surround the display region DA, and may be printed with a specific color.

The display device DD may be used for a large electronic device, such as a television, a monitor, or an outer billboard. In addition, the display device DD may be used for small and medium display devices, such as a personal computer, a laptop computer, a personal digital terminal, a car navigation system, a game console, a smartphone, a tablet, or a camera. However, the above examples are provided only as one or more embodiments, and it is obvious that the display device DD may be applied to any other electronic device(s) without departing from the concept of the present disclosure.

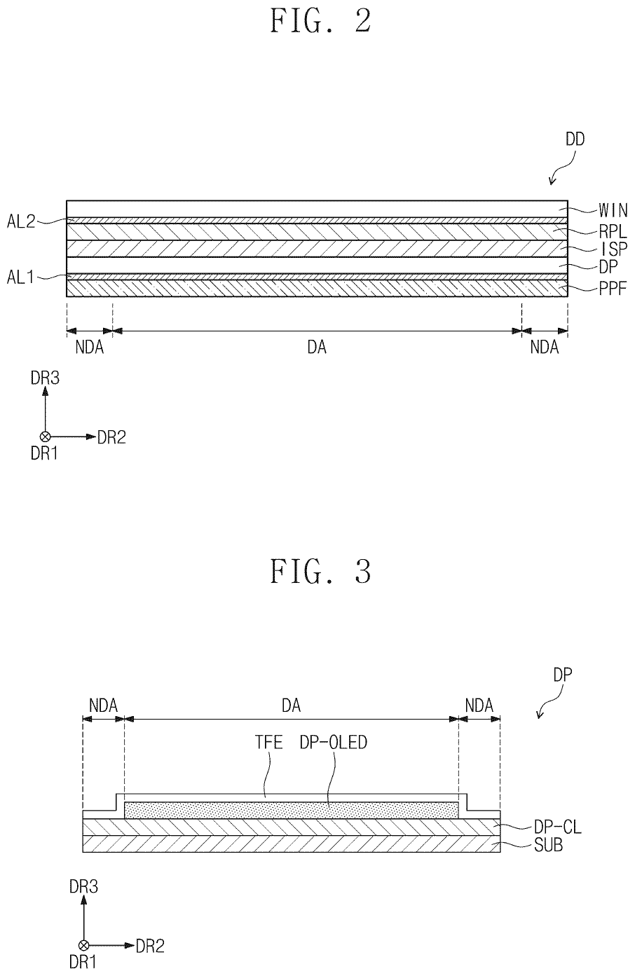

FIG. 2 is a cross-sectional view illustrating a display device illustrated in FIG. 1.

For example, FIG. 2 illustrates a cross-sectional view of a display device DD when viewed in the first direction DR1.

Referring to FIG. 2, the display device DD may include a display panel DP, an input sensor ISP, an anti-reflective layer RPL, a window WIN, a panel protecting film PPF, and first to second adhesive layers AL1 to AL2.

The display panel DP may be a flexible display panel. According to one or more embodiments of the present disclosure, the display panel DP may be a light emissive-type display panel, but the present disclosure is not limited thereto. For example, the display panel DP may be an organic light-emitting display panel or an inorganic light-emitting display panel. The light-emitting layer of the organic light-emitting display layer may include an organic light-emitting material. The light-emitting layer of the inorganic light-emitting display panel may include a quantum dot, or a quantum rod. Hereinafter, the display panel DP is an organic light-emitting display panel.

The input sensor ISP may be directly located on the display panel DP. In one or more embodiments, the input sensor ISP may include a plurality of sensors to sense an external input in a capacitive manner. The input sensor ISP may be directly formed on the display panel DP when manufacturing the display device DD. However, the present disclosure is not limited thereto. The input sensor ISP is manufactured separately from the display panel DP, and may be attached to the display panel DP by the adhesive layer.

The anti-reflective layer RPL may be located on the input sensor ISP. The anti-reflective layer RPL may be located on the input sensor ISP when the display device DD is manufactured. However, the present disclosure is not limited thereto. The anti-reflective layer RPL may be manufactured using an additional panel, and may be attached to the input sensor ISP through the adhesive layer.

The anti-reflective layer RPL may be defined as a film to reduce or prevent reflection of external light. The anti-reflective layer RPL may reduce the reflectance of external light incident from the top surface of the display device DD toward the display panel DP. In this case, the external light may not be viewed by the user by the anti-reflective layer RPL.

When the external light toward the display panel DP is reflected from the display panel DP, and then provided again to an external user, the user may view the external light, which is similar to a mirror. To reduce or prevent the likelihood of the above phenomenon, the anti-reflective layer RPL may include a plurality of color filters to display the same color as that of the pixels of the display panel DP.

The color filters may filter the external light in the same color as that of the pixels. In this case, the external light may not be viewed by the user. However, the present disclosure is not limited thereto. For example, the anti-reflective layer RPL may include a phase retarder and/or a polarizer, to reduce the reflective index of the external light.

The window WIN may be located on the anti-reflective layer RPL. The window WIN may protect the display panel DP, the input sensor ISP, and the anti-reflective layer RPL from external scratches and impacts.

The panel protecting film PPF may be located under the display panel DP. The panel protecting film PPF may protect a bottom surface of the display panel DP. The panel protecting film PPF may include a flexible plastic material, such as polyethyleneterephthalate (PET).

The first adhesive layer AL1 may be located between the display panel DP and the panel protecting film PPF, and the display panel DP and the panel protecting film PPF may be combined with each other by the first adhesive layer AL1. The second adhesive layer AL2 may be located between the window WIN and the anti-reflective layer RPL to combine the window WIN with the anti-reflective layer RPL by the second adhesive layer AL2.

FIG. 3 is a cross-sectional view illustrating a display panel illustrated in FIG. 2.

For example, FIG. 3 illustrates a cross-sectional view of the display panel DP when viewed in the first direction DR1.

Referring to FIG. 3, the display panel DP may include a substrate SUB, a circuit element layer DP-CL located on the substrate SUB, a display element layer DP-OLED located on the circuit element layer DP-CL, and a thin film encapsulating layer TFE located on the display element layer DP-OLED.

The substrate SUB may include the display region DA, and the non-display region NDA around the display region DA. The substrate SUB may include a flexible plastic material, such as glass or polyimide (PI). The display element layer DP-OLED is located in the display region DA.

A plurality of pixels may be located on the circuit element layer DP-CL and the display element layer DP-OLED. Each of the pixels may include a transistor located in the circuit element layer DP-CL, and a light-emitting element located in the display element layer DP-OLED to be connected to the transistor.

The thin film encapsulating layer TFE may be located on the circuit element layer DP-CL to cover the display element layer DP-OLED. The thin film encapsulating layer TFE may protect pixels from moisture, oxygen, and external foreign substances.

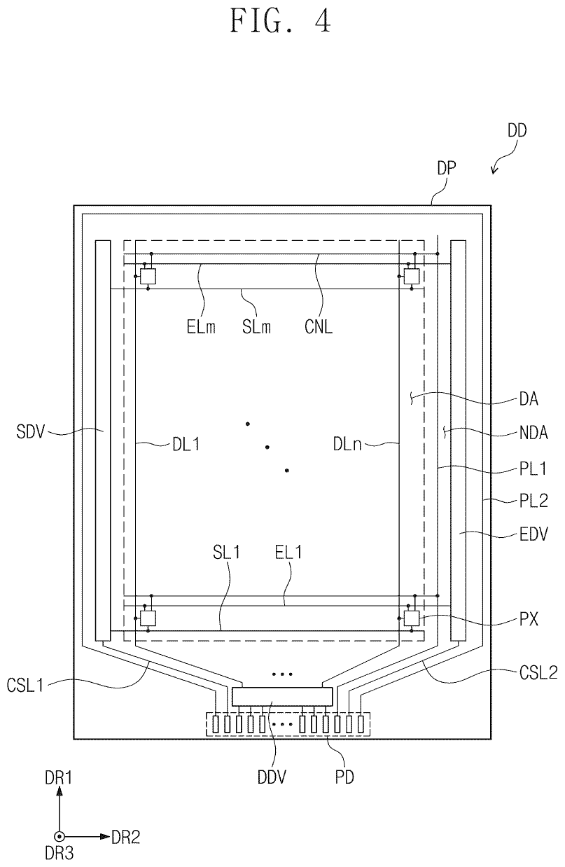

FIG. 4 is a plan view of a display panel illustrated in FIG. 2.

Referring to FIG. 4, the display device DD may include the display panel DP, a scan driver SDV, a data driver DDV, a light-emitting driver EDV, and a plurality of pads PD.

Although the display panel DP may have the shape of a rectangle having a longer side extending in the first direction DR1 and a shorter side extending in the second direction DR2, the shape of the display panel DP is not limited thereto. The display panel DP may include the display region DA and the non-display region NDA surrounding the display region DA.

The display panel DP may include a plurality of pixels PX, a plurality of scan lines SL1 to SLm, a plurality of data lines DL1 to DLn, a plurality of light-emitting lines EL1 to ELm, first and second control lines CSL1 and CSL2, first and second power lines PL1 and PL2, and connecting lines CNL. In this case, ‘m’ and ‘n’ are natural numbers.

In one or more embodiments, the display panel DP may include a sensor to sense a fingerprint. In other words, the sensor may be embedded in the display panel to sense the fingerprint, instead of being manufactured through an additional module. The sensor may include a plurality of sensors located between the pixels. The arrangement position of the sensors will be described in detail below.

The pixels PX may be located in the display region DA. The scan driver SDV and the light-emitting driver EDV may be located in the non-display region NDA adjacent to the longer sides of the display panel DP, respectively. The data driver DDV may be located in the non-display region NDA adjacent to one of the shorter sides of the display panel DP. When viewed in a plan view, the data driver DDV may be adjacent to a bottom end of the display panel DP.

The scan lines SL1 to SLm may extend in the second direction DR2 to be connected to the pixels PX and the scan driver SDV. The data lines DL1 to DLn may extend in the first direction DR1 to be connected to the pixels PX and the data driver DDV. The light-emitting lines EL1 to ELm may extend in the second direction DR2, and may be connected to the pixels PX and the light-emitting driver EDV.

The first power line PL1 may extend in the first direction DR1 and may be located in the non-display region NDA. The first power line PL1 may be located between the display region DA and the light-emitting driver EDV.

The connecting lines CNL may extend in the second direction DR2, may be arranged in the first direction DR1, and may be connected to the first power line PL1 and the pixels PX. The first voltage may be applied to the pixels PX through the first power line PL1 and the connecting lines CNL connected to each other.

The second power line PL2 may be located in the non-display region NDA, and may extend along the longer sides of the display panel DP and another shorter side of the display panel DP at which the data driver DDV is not located. The second power line PL2 may be located outside the scan driver SDV and the light-emitting driver EDV.

In one or more embodiments, the second power line PL2 may extend toward the display region DA to be connected to the pixels PX. A second voltage having a level that is lower than a first voltage may be applied to the pixels PX through the second power line PL2.

The first control line CSL1 may be connected to the scan driver SDV, and may extend toward the lower end portion of the display panel DP. The second control line CSL2 may be connected to the light-emitting driver EDV, and may extend toward the lower end portion of the display panel DP. The data driver DDV may be located between the first control line CSL1 and the second control line CSL2.

The pads PD may be located in the non-display region NDA adjacent to the lower end portion of the display panel DP, and may be more adjacent to the lower end portion of the display panel DP rather than the data driver DDV. The data driver DDV, the first and second power lines PL1 and PL2, and the first and second control lines CSL1 and CSL2 may be connected to the pads PD. The data lines DL1 to DLn may be connected to the data driver DDV. The data driver DDV may be connected to the pads PD corresponding to the data lines DL1 to DLn.

In one or more embodiments, the display device DD may further include a timing controller to control operations of the scan driver SDV, the data driver DDV, and the light-emitting driver EDV, and may further include a voltage generator to generate first and second voltages. The timing controller and the voltage generator may be mounted on the printed circuit board, and may be connected to the pads PD through the print circuit board.

The scan driver SDV generates a plurality of scan signals, and the scan signals may be applied to the pixels PX through the scan lines SL1 to SLm. The data driver DDV may generate a plurality of data voltages. The data voltages may be applied to the pixels PX through the data lines DL1 to DLn. The light-emitting driver EDV may generate a plurality of light-emitting signals, and the light-emitting signals may be applied to the pixels PX through the light-emitting lines EL1 to ELm.

The pixels PX may receive data voltages in response to the scan signals. The pixels PX may display the image as the pixels PX emit light having brightness corresponding to data voltages in response to the light-emitting signals.

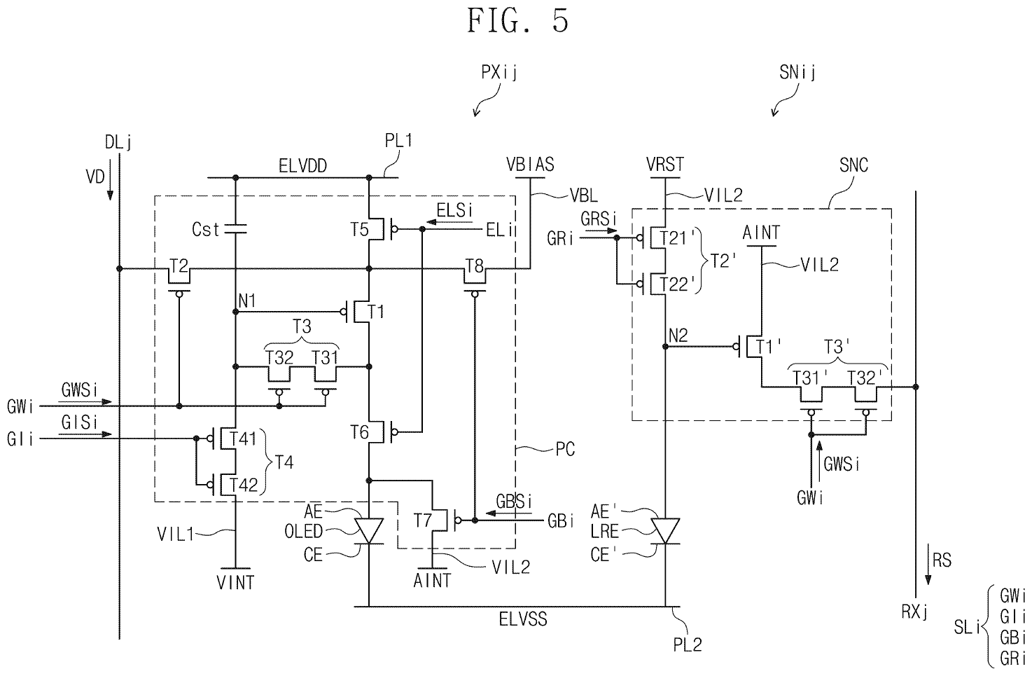

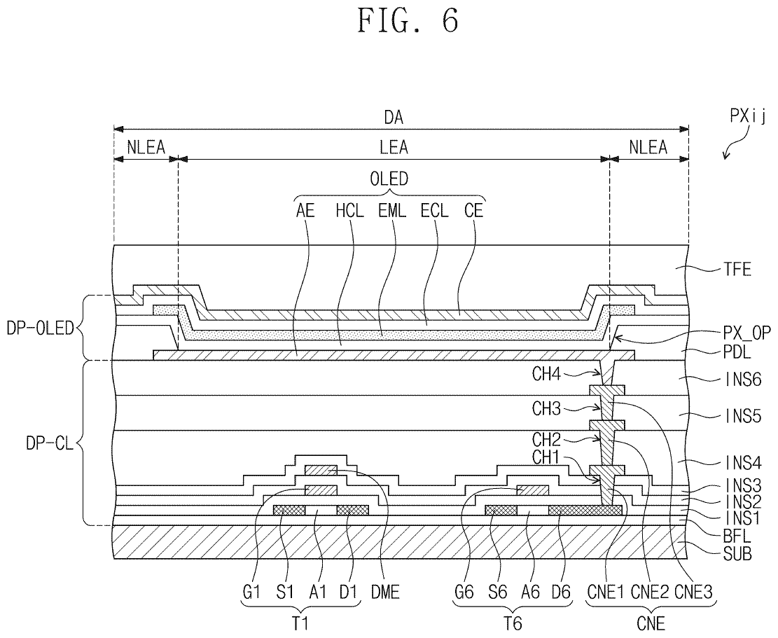

FIG. 5 is a view illustrating an equivalent circuit of any one pixel of pixels illustrated in FIG. 4 and a sensor adjacent to the pixel.

For example, FIG. 5 illustrates a pixel PXij connected to an i-th scan line SLi, an i-th light-emitting line ELi, and a j-th data line DLj. In addition, FIG. 5 illustrates a sensor SNij connected to an i-th reset line GRi and a j-th receive line RXj. In this case, “i” and “j” are natural numbers.

Referring to FIG. 5, the pixel PXij may include a pixel circuit PC, and a light-emitting element OLED connected to the pixel circuit PC. The pixel circuit PC may drive the light-emitting element OLED.

The pixel circuit PC may include a plurality of transistors T1, T2, T3, T4, T5, T6, T7, and T8 and a capacitor CST. The transistors T1, T2, T3, T4, T5, T6, T7, and T8 and the capacitor CST may control an amount of current flowing through the light-emitting element OLED. The light-emitting element OLED may generate light having specific brightness based on an amount of current provided.

The i-th scan line SLi may include an i-th write scan line GWi, an i-th initializing scan line Gli, and an i-th bias scan line GBi. The i-th write scan line GWi may receive an i-th write scan signal GWSi, the i-th initializing scan line Gli may receive an i-th initializing scan signal GISi, and the i-th bias scan line GBi may receive an i-th bias scan signal GBSi.

The i-th light-emitting line ELi may receive an i-th light-emitting signal ELSi. The i-th reset line GRi may receive an i-th reset scan signal GRSi.

The i-th write scan line GWi, the i-th initializing scan line Gli, the i-th bias scan line GBi, the i-th light-emitting line ELi, and the i-th reset line GRi may be defined as control lines. The i-th write scan line GWi may be defined as a first control line, and the i-th initializing scan line Gli may be defined as a second control line. The i-th light-emitting line ELi may be defined as a third control line, and the i-th bias scan line GBi may be defined as a fourth control line. The i-th reset line GRi may be defined as a fifth control line.

The pixel circuit PC may be connected to the j-th data line DLj, the i-th write scan line GWi, the i-th initializing scan line Gli, the i-th bias scan line GBi, the i-th light-emitting line ELi, a first initializing line VIL1, a second initializing line VIL2, a bias line VBL, and the first and second power lines PL1 and PL2. The first initializing line VIL1 may receive a first initializing voltage VINT, the second initializing line VIL2 may receive a second initializing voltage AINT, and the bias line VBL may receive a bias voltage VBIAS.

The first to eighth transistors T1, T2, T3, T4, T5, T6, T7, and T8 may each include a source electrode, a drain electrode, and a gate electrode. Hereinafter, as illustrated in FIG. 5, any one of the source electrode or the drain electrode is defined as the first electrode, and another one of the source electrode and the drain electrode is defined as the second electrode. In addition, the gate electrode is defined as a control electrode.

The first to eighth transistors T1, T2, T3, T4, T5, T6, T7, and T8 may include one or more PMOS transistors, but the present disclosure is not limited thereto, and the first to eighth transistors T1, T2, T3, T4, T5, T6, T7, and T8 may include one or more NMOS transistors.

The first transistor T1 may be defined as a driving transistor, and the second transistor T2 may be defined as a switching transistor. The third transistor T3 may be defined as a compensating transistor. The fourth transistor T4 and the seventh transistor T7 may be defined as initializing transistors. The fifth transistor T5 and the sixth transistor T6 may be defined as light-emitting control transistors. The eighth transistor T8 may be defined as a bias transistor.

The light-emitting element OLED may be defined as an organic light-emitting device. The light-emitting element OLED may include an anode AE and a cathode CE. The anode AE may receive a first voltage ELVDD through the sixth, first, and fifth transistors T6, T1, and T5. The first voltage ELVDD may be applied to the pixel circuit PC through the first power line PL1. The cathode CE may receive a second voltage ELVSS having a level lower than the first voltage ELVDD. The second voltage ELVSS may be applied to the pixel circuit PC through the second power line PL2.

The first transistor T1 is connected between the anode AE and the first power line PL1, and may be switched by a voltage at a first node N1. For example, the first transistor T1 may be connected between the fifth transistor T5 and the sixth transistor T6. The first transistor T1 may be connected to the first power line PL1 through the fifth transistor T5, and may be connected to the anode AE through the sixth transistor T6.

The first transistor T1 may include a first electrode connected to the first power line PL1 through the fifth transistor T5, a second electrode connected to the anode AE through the sixth transistor T6, and a control electrode connected to the first node N1. The first electrode of the first transistor T1 may be connected to the fifth transistor T5, and the second electrode of the first transistor T1 may be connected to the sixth transistor T6. The first transistor T1 may control an amount of current flowing through the light-emitting element OLED depending on the voltage at the first node N1, which is applied to the control electrode of the first transistor T1.

The second transistor T2 may be connected between the first transistor T1 and the j-th data line DLj, and may be switched by the write scan signal GWSi. The second transistor T2 may be connected between the first electrode of the first transistor T1 and the j-th data line DLj. The second transistor T2 may include a first electrode connected to the j-th data line DLj, a second electrode connected to the first electrode of the first transistor T1, and a control electrode connected to the i-th write scan line GWi.

The second transistor T2 may be turned on by the i-th write scan signal GWSi applied through the i-th write scan line GWi to electrically connect the j-th data line DLj to the first electrode of the first transistor T1. The second transistor T2 may perform a switching operation for supplying a data voltage VD applied through the j-th data line DLj to the first electrode of the first transistor T1.

The third transistor T3 may be connected to the first node N1 and the anode AE, and may be switched by the i-th write scan signal GWSi. The third transistor T3 may be connected to the anode AE through the sixth transistor T6. The third transistor T3 may be connected between the second electrode of the first transistor T1 and the first node N1. The third transistor T3 may include a first electrode connected to the second electrode of the first transistor T1, a second electrode connected to the first node N1, and a control electrode connected to the i-th write scan line GWi.

The third transistor T3 may be turned on by the i-th write scan signal GWSi applied through the i-th write scan line GWi to electrically connect the second electrode of the first transistor T1 and the control electrode of the first transistor T1. When the third transistor T3 is turned on, the first transistor T1 may be connected in the form of a diode.

The third transistor T3 may have a dual-gate structure to reduce a leakage current. For example, the third transistor T3 may include two sub-transistors T31 and T32. In the dual-gate structure, two gate electrodes (control electrodes) are connected to each other to have the same potential, and a channel length may be longer than a channel length in a single gate structure. As the channel length is increased, resistance is increased, and thus the leakage current is decreased when turned off. Accordingly, the stability of operation may be ensured.

The fourth transistor T4 may be connected between the first node N1 and the first initializing line VIL1, and may be switched by the i-th initializing scan signal GISi. The fourth transistor T4 may include a first electrode connected to the first node N1, a second electrode connected to the first initializing line VIL1, and a control electrode connected to the i-th initializing scan line Gli.

The fourth transistor T4 may be turned on by the i-th initializing scan signal GISi applied through the i-th initializing scan line Gli and may supply the first initializing voltage VINT applied through the first initializing line VIL1 to the first node N1. Similar to the third transistor T3, the fourth transistor T4 may have a dual-gate structure to reduce a leakage current. For example, the fourth transistor T4 may include two sub-transistors T41 and T42.

The fifth transistor T5 may be connected between the first power line PL1 and the first transistor T1. The fifth transistor T5 may include a first electrode connected to the first power line PL1, a second electrode connected to the first electrode of the first transistor T1, and a control electrode connected to the i-th light-emitting line ELi.

The sixth transistor T6 may be connected between the first transistor T1 and the anode AE. The sixth transistor T6 may include a first electrode connected to the second electrode of the first transistor T1, a second electrode connected to the anode AE, and a control electrode connected to the i-th light-emitting line ELi.

The fifth transistor T5 and the sixth transistor T6 may be turned on by the i-th light-emitting signal ELSi applied through the i-th light-emitting line ELi. The first voltage ELVDD is provided to the light-emitting element OLED by the fifth transistor T5 and the sixth transistor T6 that are turned on, such that a driving current may flow through the light-emitting element OLED. Therefore, the light-emitting element OLED may emit light.

The seventh transistor T7 may include a first electrode connected to the anode AE, a second electrode connected to the second initializing line VIL2, and a control electrode connected to the i-th bias scan line GBi. The seventh transistor T7 may be turned on by the i-th bias scan signal GBSi applied through the i-th bias scan line GBi to supply the second initializing voltage AINT received through the second initializing line VIL2 to the anode AE of the light-emitting element OLED.

According to one or more embodiments of the present disclosure, the seventh transistor T7 may be omitted. According to one or more embodiments of the present disclosure, the second initializing voltage AINT may have a level that is different from the level of the first initializing voltage VINT, but the present disclosure is not limited thereto. For example, the second initializing voltage AINT may have the same level as the first initializing voltage VINT.

The seventh transistor T7 may improve the black expression ability of the pixel PX. When the seventh transistor T7 is turned on, a parasitic capacitor of the light-emitting element OLED may be discharged. Accordingly, when implementing the brightness of a black grayscale, the light-emitting element OLED does not emit light due to the leakage current of the first transistor T1. Accordingly, the black expression ability may be improved.

The capacitor CST may include a first electrode connected to the first power line PL1, and a second electrode connected to the first node N1. When the fifth transistor T5 and the sixth transistor T6 are turned on, the amount of current flowing through the first transistor T1 may be determined depending on the voltage stored in the capacitor CST.

The eighth transistor T8 may be connected to the first electrode of the first transistor T1, may receive the bias voltage VBIAS, and may be switched by the i-th bias scan signal GBSi. The eighth transistor T8 may include a first electrode for receiving the bias voltage VBIAS, a second electrode connected to the first electrode of the first transistor T1, and a control electrode connected to the i-th bias scan line GBi.

The eighth transistor T8 may be turned on by the i-th bias scan signal GBSi, and may provide the bias voltage VBIAS to the first electrode of the first transistor T1. When the bias voltage VBIAS is applied to the first transistor T1, the shift of the hysteresis curve of the first transistor T1 may be suppressed.

The sensor SNij may include a sensor circuit SNC and a light-receiving element LRE connected to the sensor circuit SNC. The sensor circuit SNC may drive the light-receiving element LRE. The sensor circuit SNC may be connected to the i-th write scan line GWi, the i-th reset line GRi, the j-th receive line RXj, and the second initializing line VIL2. The i-th scan line SLi may further include the i-th reset line GRi, and the i-th reset line GRi may be defined as a sensing-control line.

The sensor circuit SNC may include a first transistor T1′, a second transistor T2′, and a third transistor T3′. One or more of the first to third transistors T1′, T2′, and T3′ may include PMOS transistors, but the present disclosure is not limited thereto, and one or more of the first to third transistors T1′, T2′, and T3′ may include NMOS transistors.

The second and third transistors T2′ and T3′ may have a dual-gate structure similar to that of the third and fourth transistors T3 and T4 described above. For example, the second transistor T2′ may include two sub-transistors T21′ and T22′, and the third transistor T3′ may include two sub-transistors T31′ and T32′.

The first transistor T1′ may be connected to the light-receiving element LRE, the second transistor T2′, and the third transistor T3′. The light-receiving element LRE may include a photodiode. The light-receiving element LRE may convert light energy incident from the outside into electrical energy. The light-receiving element LRE may include an anode AE′ and a cathode CE′. The anode AE′ may be connected to a second node N2, and the cathode CE′ may be connected to the second power line PL2.

The first transistor T1′ may include a first electrode for receiving the second initializing voltage AINT, a control electrode connected to the anode AE′ through the second node N2, and a second electrode connected to the third transistor T3′. The first electrode of the first transistor T1′ may be connected to the second initializing line VIL2 to receive the second initializing voltage AINT.

The second transistor T2′ may include a first electrode to receive a reset voltage VRST, a control electrode connected to the i-th reset line GRi, and a second electrode connected to the anode AE′ through the second node N2. According to one or more embodiments of the present disclosure, the reset voltage VRST may be set to the same voltage as the second initializing voltage AINT. Accordingly, the first electrode of the second transistor T2′ may be connected to the second initializing line VIL2.

The third transistor T3′ may include a first electrode connected to the second electrode of the first transistor T1′, a control electrode connected to the i-th write scan line GWi, and a second electrode connected to the receive line RXj. The third transistor T3′ may be turned on by the i-th write scan signal GWSi received through the i-th write scan line GWi.

The second transistor T2′ may be turned on by an i-th reset signal GRSi received through the i-th reset line GRi. The turned-on second transistor T2′ may receive the reset voltage VRST, and may provide the same to the second node N2.

The second node N2 may be reset by the reset voltage VRST.

The i-th write scan signal GWSi may be applied to the control electrode of the third transistor T3′ such that the third transistor T3′ may be turned on. The first transistor T1′ may be connected to the receive line RXj by the turned-on third transistor T3′.

The light-receiving element LRE receives light, and converts the light into an electric signal. In this case, the voltage of the second node N2 may be changed. When the first transistor T′ is turned on, the second initializing voltage AINT provided to the first transistor T1′ may be controlled depending on a change in voltage of the second node N2, and may be provided to the receive line RXj through the third transistor T3′. Accordingly, a signal sensed by the light-receiving element LRE may be outputted through the receive line RXj as a sensing signal RS.

FIG. 6 is a cross-sectional view illustrating a light-emitting element, a first transistor, and a sixth transistor of a pixel illustrated in FIG. 5.

Referring to FIG. 6, the light-emitting element OLED may include a first electrode AE, a second electrode CE, a hole control layer HCL, an electron control layer ECL, and a light-emitting layer EML. The first electrode AE may be an anode AE illustrated in FIG. 5, and the second electrode CE may be a cathode CE illustrated in FIG. 5. The second electrode CE may be located on (e.g., above) the first electrode AE, and the hole control layer HCL, the electron control layer ECL, and the light-emitting layer EML may be located between the first electrode AE and the second electrode CE.

The first and sixth transistors T1 and T6 and the light-emitting element OLED may be located on the substrate SUB. The display region DA may include a light-emitting region LEA corresponding to the pixel PXij, and a non-light-emitting region NLEA adjacent to the light-emitting region LEA. The light-emitting element OLED may be located in the light-emitting region LEA.

A buffer layer BFL may be located on the substrate SUB, and may be an inorganic layer. Semiconductor layers S1, A1, and D1 of the first transistor T1 and semiconductor layers S6, A6, and D6 of the sixth transistor T6 may be located on the buffer layer BFL. The semiconductor layers S1, A1, D1, S6, A6, and D6 may include polysilicon. However, the present disclosure is not limited thereto, and the semiconductor layers S1, A1, D1, S6, A6, and D6 may include amorphous silicon.

The semiconductor layers S1, A1, D1, S6, A6, and D6 may be doped with an N-type dopant or a P-type dopant. The semiconductor layers S1, A1, D1, S6, A6, and D6 may include a heavily-doped region and a lightly-doped region. The conductivity of the heavily-doped region (e.g., the source region and the drain region) is greater than that of the lightly-doped region, and may substantially serve as a source electrode and a drain electrode of the first and sixth transistors T1 and T6. The lightly-doped region may substantially correspond to the channel region (or channel) of the first and sixth transistors T1 and T6.

The first source region S1, the first channel region A1, and the first drain region D1 of the first transistor T1 may be formed from the semiconductor layers S1, A1, and D1. The sixth source region S6, the sixth channel region A6, and the sixth drain region D6 of the sixth transistor T6 may be formed from the semiconductor layers S6, A6, and D6. The first channel region A1 may be located between the first source region S1 and the first drain region D1. The sixth channel region A6 may be located between the sixth source region S6 and the sixth drain region D6.

A first insulating layer INS1 may be located on the buffer layer BFL to cover the semiconductor layers S1, A1, D1, S6, A6, and D6. The first and sixth gate electrodes G1 and G6 (or control electrodes) of the first and sixth transistors T1 and T6 may be located on the first insulating layer INS1.

In one or more embodiments, other transistors T2, T3, T4, T5, T7, and/or T8 may have substantially the same structure as that of the first and sixth transistors T1 and T6.

A second insulating layer INS2 may be located on (e.g., above) the first insulating layer INS1 to cover the first and sixth gate electrodes G1 and G6. A dummy electrode DME may be located on the second insulating layer INS2. The dummy electrode DME may be located on the first gate electrode G1, and may overlap the first gate electrode G1 when viewed in a plan view.

The dummy electrode DME may form the above-described capacitor CST together with the first gate electrode G1. The dummy electrode DME may define a first electrode of the capacitor CST, and the first gate electrode G1 may define a second electrode of the capacitor CST.

A third insulating layer INS3 may be located on (e.g., above) the second insulating layer INS2 to cover the dummy electrode DME. The buffer layer BFL and the first to third insulating layers INS1, INS2, and INS3 may include inorganic layers.

A connection electrode CNE may be located between the sixth transistor T6 and the light-emitting element OLED. The connection electrode CNE may electrically connect the sixth transistor T6 to the light-emitting element OLED. The connection electrode CNE may include a first connection electrode CNE1, a second connection electrode CNE2 located on (e.g., above) the first connection electrode CNE1, and a third connection electrode CNE3 located on (e.g., above) the second connection electrode CNE2.

The first connection electrode CNE1 may be located on (e.g., above) the third insulating layer INS3, and may be connected to the sixth drain region D6 through a first contact hole CH1 defined in the first to third insulating layers INS1, INS2, and INS3. A fourth insulating layer INS4 may be located on (e.g., above) the third insulating layer INS3 to cover the first connection electrode CNE1.

The second connection electrode CNE2 may be located on (e.g., above) the fourth insulating layer INS4. The second connection electrode CNE2 may be connected to the first connection electrode CNE1 through a second contact hole CH2 defined in the fourth insulating layer INS4. A fifth insulating layer INS5 may be located on (e.g., above) the fourth insulating layer INS4 to cover the second connection electrode CNE2.

The third connection electrode CNE3 may be located on (e.g., above) the fifth insulating layer INS5. The third connection electrode CNE3 may be connected to the second connection electrode CNE2 through a third contact hole CH3 defined in the fifth insulating layer INS5. A sixth insulating layer INS6 may be located on (e.g., above) the fifth insulating layer INS5 to cover the third connection electrode CNE3. The fourth to sixth insulating layers INS4, INS5, and INS6 may include an inorganic layer or an organic layer.

The first electrode AE may be located on (e.g., above) the sixth insulating layer INS6. The first electrode AE may be electrically connected to the third connection electrode CNE3 through a fourth contact hole CH4 defined in the sixth insulating layer INS6.

A pixel-defining layer PDL to expose a specific portion of the first electrode AE may be located on (e.g., above) the first electrode AE and the sixth insulating layer INS6. An opening PX_OP for exposing a specific portion of the first electrode AE may be defined in the pixel-defining layer PDL.

The hole control layer HCL may be located on (e.g., above) the first electrode AE and the pixel-defining layer PDL. The hole control layer HCL may be located in common in the light-emitting region LEA and the non-light-emitting region NLEA. The hole control layer HCL may include a hole transport layer and a hole injection layer.

The light-emitting layer EML may be located on (e.g., above) the hole control layer HCL. The light-emitting layer EML may be located in a region corresponding to the opening PX_OP. The light-emitting layer EML may include an organic material and/or an inorganic material. The light-emitting layer EML may generate any one of red, green, or blue light.

The electron control layer ECL may be located on (e.g., above) the light-emitting layer EML and the hole control layer HCL. The electron control layer ECL may be located in common in the light-emitting region LEA and the non-light-emitting region NLEA. The electron control layer ECL may include an electron transport layer and an electron injection layer.

The second electrode CE may be located on (e.g., above) the electron control layer ECL. The second electrode CE may be located in common with the pixels PX. In other words, the second electrode CE may be located on the light-emitting layers EML of the pixels PX in common.

The layers from the buffer layer BFL to the sixth insulating layer INS6 may be collectively defined as the circuit element layer DP-CL. The layer having the light-emitting diode OLED located therein may be defined as the display element layer DP-OLED.

The thin film encapsulating layer TFE may be located on the light-emitting element OLED. The thin film encapsulating layer TFE may include an inorganic layer, an organic layer, and another inorganic layer sequentially stacked. The inorganic layers include an inorganic material and may protect pixels from moisture/oxygen. The organic layer includes an organic material and may protect the pixels PX from foreign substances, such as dust particles.

The first voltage ELVDD may be applied to the first electrode AE, and the second voltage ELVSS may be applied to the second electrode CE. Holes and electrons injected into the light-emitting layer EML combine to each other to form an exciton, and the light-emitting element OLED may emit light, as the exciton transitions to the bottom state. The light-emitting element OLED emits light to display an image.

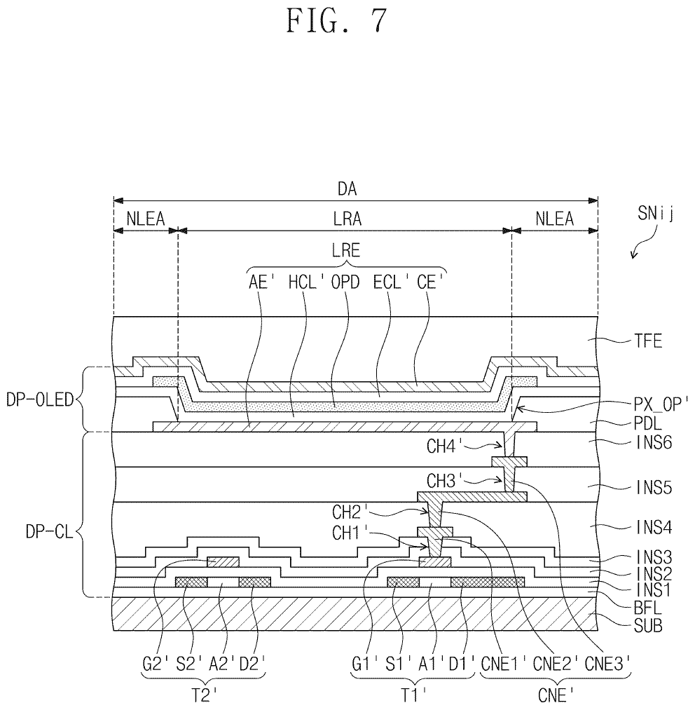

FIG. 7 is a cross-sectional view illustrating a light-receiving element, a first transistor, and a second transistor of the sensor illustrated in FIG. 5.

Hereinafter, the configuration illustrated in FIG. 7 will be described while focusing a structure different from the stack structure illustrated in FIG. 6.

Referring to FIG. 7, the display region DA may include a light-receiving region LRA corresponding to the sensor SNij, and the non-light-emitting region NLEA adjacent to the light-receiving region LRA. The non-light-emitting region NLEA may be the non-light-emitting region NLEA illustrated in FIG. 7.

The light-receiving element LRE may include a first electrode AE′, a second electrode CE′, a hole control layer HCL′, an electron control layer ECL′, and a light-receiving layer OPD. The first electrode AE′ may be the anode AE′ illustrated in FIG. 5, and the second electrode CE′ may be the cathode CE′ illustrated in FIG. 5.

The light-receiving layer OPD may be defined as an organic photodiode. The first electrode AE′, the second electrode CE′, the hole control layer HCL′, and the electron control layer ECL′ may be respectively substantially the same as the first electrode AE, the second electrode CE, the hole control layer HCL, and the electron control layer ECL illustrated in FIG. 6.

In FIG. 7, a position at which the light-receiving layer OPD is located may correspond to a position at which the light-emitting layer EML is located in FIG. 6. In other words, the second electrode CE′ may be located on (e.g., above) the first electrode AE′, and the hole control layer HCL′, the electron control layer ECL′, and the light-receiving layer OPD may be located between the first electrode AE′ and the second electrode CE′. The second electrode CE′ may be located on the light-receiving layers OPD of the light-receiving elements LRE in common. The second electrode CE′ may be integrally formed with the second electrode CE illustrated in FIG. 6.

The first transistor T1′ may include a first source region S1′, a first drain region D1′, a first channel region A1′, and a first gate electrode G1′. The second transistor T2′ may include a second source region S2′, a second drain region D2′, a second channel region A2′, and a second gate electrode G2′.

The stack structure of the first and second transistors T1′ and T2′ may be substantially the same as the stack structure of the first and sixth transistors T1 and T6 illustrated in FIG. 6. In one or more embodiments, the third transistor T3′ may have the same structure as that of the first and second transistors T1′ and T2′.

A connection electrode CNE′ may include a first connection electrode CNE1′, a second connection electrode CNE2′, and a third connection electrode CNE3′. The first connection electrode CNE1′ may be located at the same layer as that of the first connection electrode CNE1 illustrated in FIG. 6, and the second connection electrode CNE2′ may be located at the same layer as that of the second connection electrode CNE2 illustrated in FIG. 6. The third connection electrode CNE3′ may be located at the same layer as that of the third connection electrode CNE3 illustrated in FIG. 6.

The first connection electrode CNE1′ may be connected to the first gate electrode G1′ of the first transistor T′ through a first contact hole CH1′ defined in the second and third insulating layers INS2 and INS3. The second connection electrode CNE2′ may be connected to the first connection electrode CNE1′ through a second contact hole CH2′ defined in the fourth insulating layer INS4.

The third connection electrode CNE3′ may be connected to the second connection electrode CNE2′ through a third contact hole CH3′ defined in the fifth insulating layer INS5. The first electrode AE′ of the light-receiving element LRE may be connected to the third connection electrode CNE3′ through a fourth contact hole CH4′ defined in the sixth insulating layer INS6.

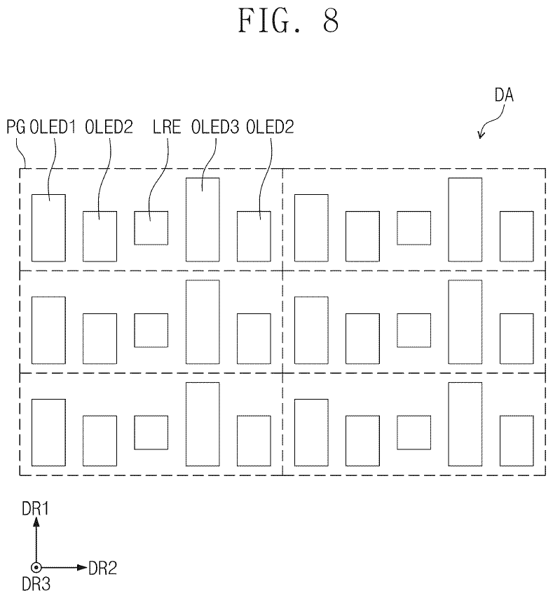

FIG. 8 is a view illustrating an arrangement state of light-emitting elements and light-receiving elements located in a partial region of the display region illustrated in FIG. 4.

Referring to FIG. 8, each of first, second, and third light-emitting elements OLED1, OLED2, and OLED3 may correspond to the light-emitting elements OLED illustrated in FIGS. 5 and 6. Each of the light-receiving elements LRE may correspond to the light-receiving element LRE illustrated in FIGS. 5 and 7. The first light-emitting elements OLED1 may express a red color. The second light-emitting elements OLED2 may express a green color. The third light-emitting elements OLED3 may display a blue color.

The first, second, and third light-emitting elements OLED1, OLED2, and OLED3 and the light-receiving elements LRE may be grouped into a plurality of pixel groups PG. For example, each of the pixel groups PG may include the first light-emitting element OLED1, the second light-emitting element OLED2, the light-receiving element LRE, the third light-emitting element OLED3, and the second light-emitting element OLED2 arranged in the second direction DR2. The pixel groups PG may be arranged in the first direction DR1 and the second direction DR2.

In each of the pixel groups PG, one second light-emitting element OLED2 may be located between the first light-emitting element OLED1 and the light-receiving element LRE, and the third light-emitting element OLED3 may be located between the light-receiving element LRE and another second light-emitting element OLED2. The light-receiving element LRE may be located between one second light-emitting element OLED2 and the third light-emitting element OLED3.

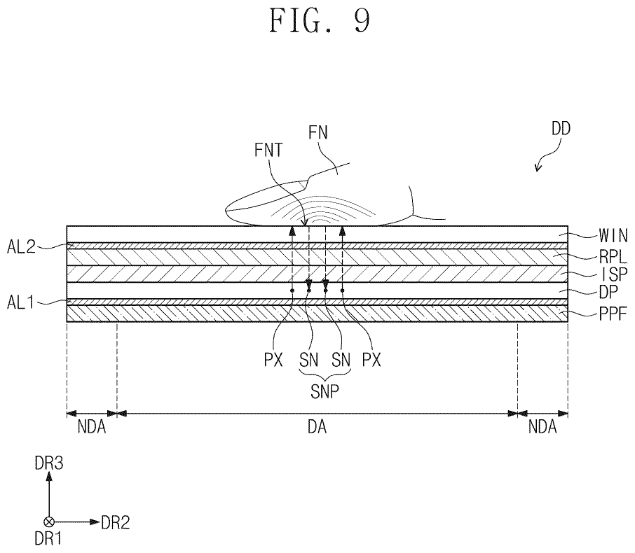

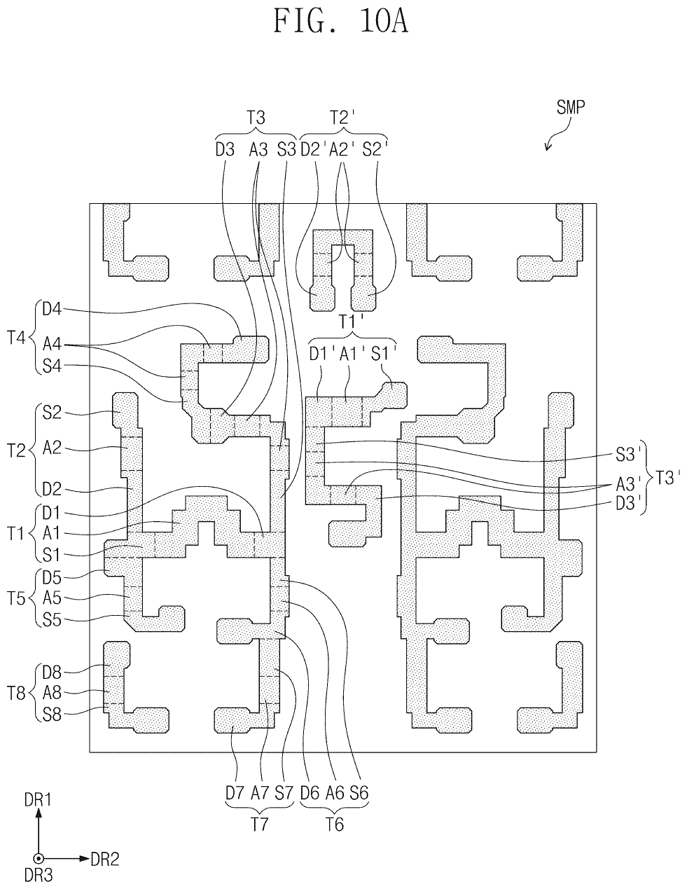

FIG. 9 is a view illustrating a fingerprint-sensing state corresponding to the sensors illustrated in FIGS. 5 and 7.

Referring to FIGS. 5, 7, and 9, the display device DD may include a sensor SNP embedded in the display panel DP, and the sensor SNP may include a plurality of sensors SN. Each of the sensors SN may have the same configuration as the sensor SNij illustrated in FIGS. 5 and 7. For example, although two sensors SN are illustrated in FIG. 9, more sensors SN may be substantially located in the display panel DP to form the sensor SNP.

The sensors SN may detect a fingerprint FNT of a finger FN provided on the display panel DP. Light generated from the light-emitting elements OLED of the pixels PX is applied to the fingerprint FNT and may be reflected from the fingerprint FNT.

Light reflected from the fingerprint FNT may be provided to the light-receiving elements LRE of the sensors SN to be sensed. The sensors SN may sense the fingerprint FNT through light reflected from the fingerprint FNT. In one or more embodiments, the control module of the display device DD may receive fingerprint information sensed by the sensors SN and perform a user authentication mode using the received fingerprint information.

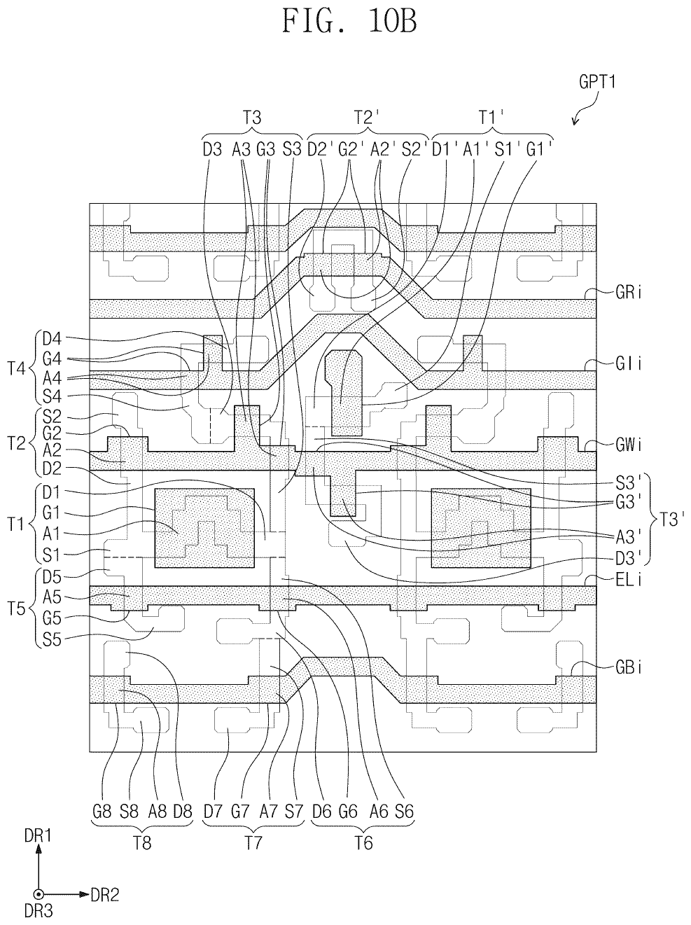

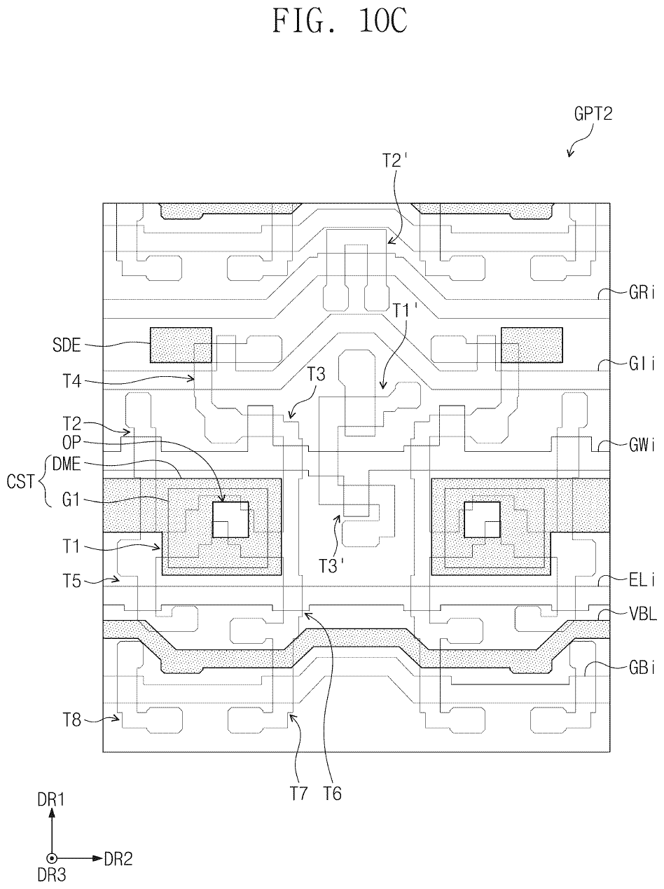

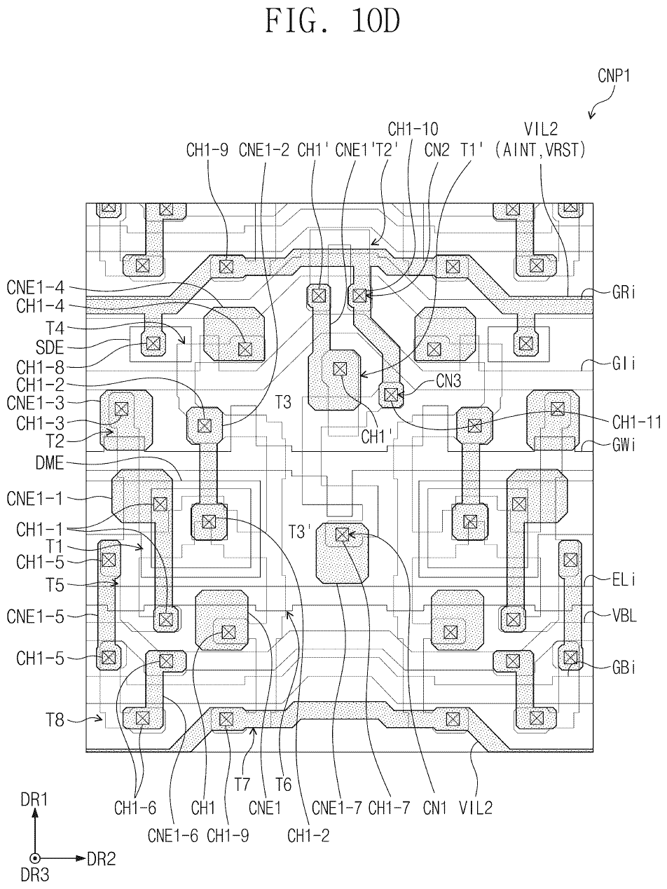

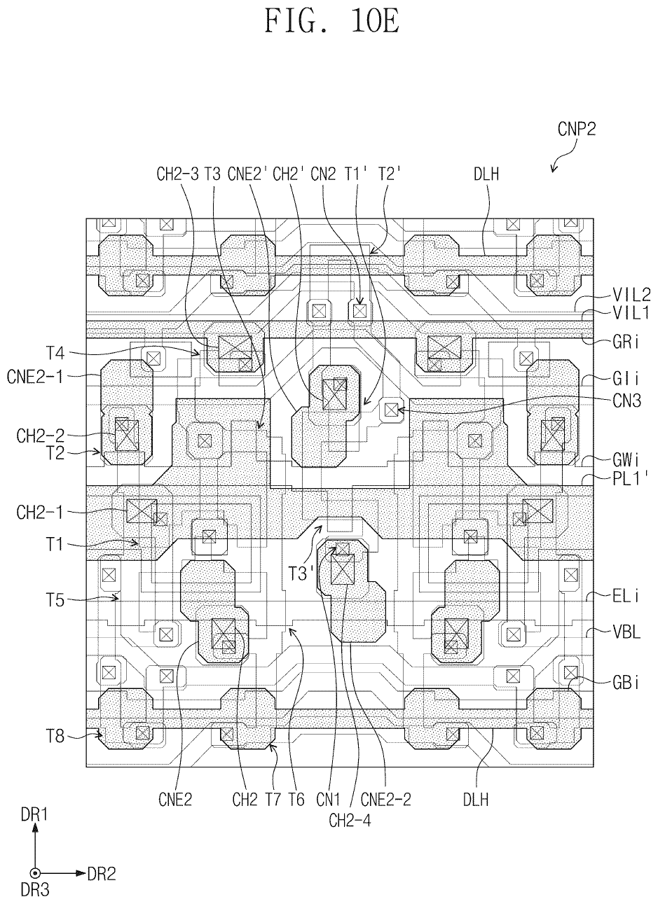

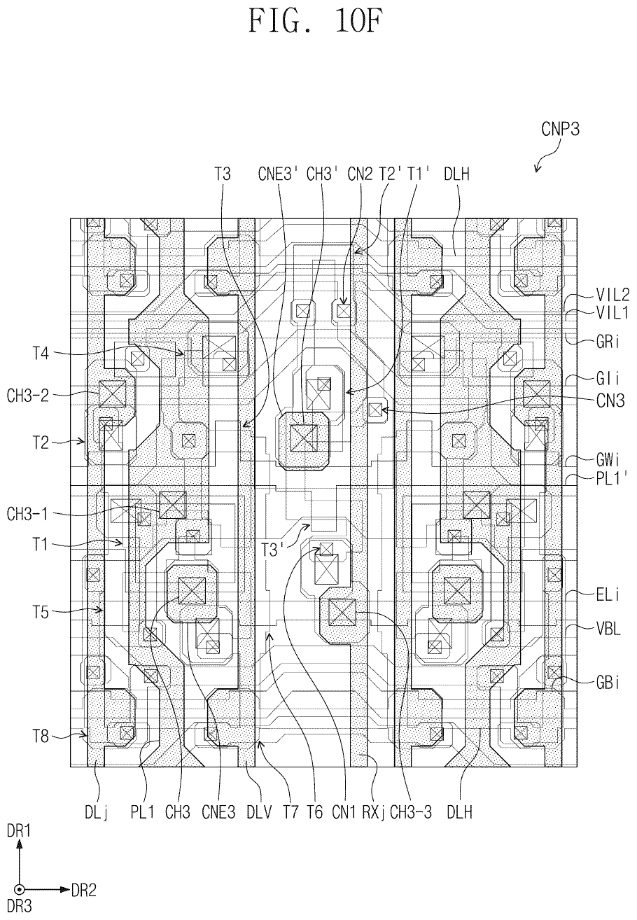

FIGS. 10A to 10F are views illustrating the structures of the pixel circuit and the sensor circuit illustrated in FIG. 5 when viewed in a plan view.

FIGS. 10A to 10F may be defined as a layout diagram of the pixel circuit PC and the sensor circuit SNC. In the description of FIGS. 10A to 10F, “overlap” indicates a state in which components overlap each other when viewed in a plan view.

Referring to FIGS. 5 and 10A, a semiconductor pattern SMP illustrated in FIG. 10A may be located on the above-described substrate SUB. The semiconductor pattern SMP is not limited to the shape illustrated in FIG. 10A, and may have various shapes.

First to eighth source regions S1, S2, S3, S4, S5, S6, S7, and S8, first to eighth drain regions D1, D2, D3, D4, D5, D6, D7, and D8, and first to eighth channel regions A1, A2, A3, A4, A5, A6, A7, and A8 of the first to eighth transistors T1, T2, T3, T4, T5, T6, T7, and T8 may be formed based on the semiconductor pattern SMP. The first to eighth channel regions A1, A2, A3, A4, A5, A6, A7, and A8 may be located between the first to eighth source regions S1, S2, S3, S4, S5, S6, S7, and S8 and the first to eighth drain regions D1, D2, D3, D4, D5, D6, D7, and D8, respectively. Each of the third and fourth channel regions A3 and A4 of the third and fourth transistors T3 and T4 having a dual-gate structure may be formed in two.

First to third source regions S1′, S2′, and S3′, first to third drain regions D1′, D2′, and D3′, and first to third channel regions A1′, A2′, and A3′ of the first to third transistors T1′, T2′, and T3′ may be formed based on the semiconductor pattern SMP. The first to third channel regions A1′, A2′, and A3′ may be located between the first to third source regions S1′, S2′, and S3′ and the first to third drain regions D1′, D2′, and D3′, respectively. Each of the second and third channel regions A2′ and A3′ of the second and third transistors T2′ and T3′ having a dual-gate structure may be formed in two.

The second drain region D2 of the second transistor T2 and the fifth drain region D5 of the fifth transistor T5 may be formed to extend from the first source region S1 of the first transistor T1. The sixth source region S6 of the sixth transistor T6 and the third source region S3 of the third transistor T3 may be formed to extend from the first drain region D1 of the first transistor T1.

The fourth source region S4 of the fourth transistor T4 may be formed to extend from the third drain region D3 of the third transistor T3. The seventh source region S7 of the seventh transistor T7 may be formed to extend from the sixth drain region D6 of the sixth transistor T6.

The semiconductor pattern SMP of the eighth transistor T8 may be adjacent to the semiconductor pattern SMP of the fifth transistor T5. The semiconductor pattern SMP of the eighth transistor T8 may be formed in an island shape.

The semiconductor pattern SMP of the first and third transistors T1′ and T3′ may be adjacent to the semiconductor pattern SMP of the third transistor T3 in the second direction DR2. The third source region S3′ of the third transistor T3′ may be formed to extend from the first drain region D1′ of the first transistor T1′. The semiconductor pattern SMP of the second transistor T2′ may be spaced apart from the semiconductor pattern SMP of the first transistor T′ in the first direction DR1.

Hereinafter, when lines illustrated in FIGS. 10B to 10F are indicated, the names of “i-th” and “j-th” are omitted.

Referring to FIGS. 5, 10A, and 10B, a first gate pattern GPT1 may be located on the semiconductor pattern SMP. The first gate pattern GPT1 may include first gate electrodes G1 and G1′, the write scan line GWi, the initializing scan line Gli, the light-emitting line ELi, the bias scan line GBi, and the reset line GRi.

The first gate electrode G1 of the first transistor T1 and the first gate electrode G1′ of the first transistor T1′ may be formed by the first gate pattern GPT1. The first gate electrode G1 may overlap the first channel region A1, and the first gate electrode G1′ may overlap the first channel region A1′.

As described above, the write scan line GWi, the initializing scan line Gli, the light-emitting line ELi, and the bias scan line GBi may be defined as first, second, third, and fourth control lines, respectively, and the reset line GRi may be defined as a sensing-control line. Hereinafter, the write scan line GWi, the initializing scan line Gli, the light-emitting line ELi, and the bias scan line GBi are referred to as first, second, third, and fourth control lines, respectively. In addition, the reset line GRi is referred to as a sensing-control line.

The first control line GWi, the second control line Gli, the third control line ELi, the fourth control line GBi, and the sensing-control line GRi may be arranged in the first direction DR1, and may extend in the second direction DR2.

The first control line GWi may be located between the second control line Gli and the third control line ELi. The second control line Gli may be located between the first control line GWi and the sensing-control line GRi. The third control line ELi may be located between the first control line GWi and the fourth control line GBi. The first gate electrode G1 may be located between the first control line GWi and the third control line ELi. The first gate electrode G1′ may be located between the first control line GWi and the second control line Gli.

The first control line GWi may extend to cross the semiconductor pattern SMP. The second gate electrode G2 of the second transistor T2, the third gate electrode G3 of the third transistor T3, and the third gate electrode G3′ of the third transistor T3′ may be formed based on the first control line GWi. Portions of the first control line Gwi that overlap the semiconductor pattern SMP may be defined as the second and third gate electrodes G2, G3, and G3′. The second and third gate electrodes G2, G3, and G3′ may overlap the second and third channel regions A2, A3, and A3′, respectively.

The second control line Gli may extend to cross the semiconductor pattern SMP. The fourth gate electrode G4 of the fourth transistor T4 may be formed by the second control line Gli. A portion of the second control line Gli, which overlaps the semiconductor pattern SMP may be defined as a fourth gate electrode G4. The fourth gate electrode G4 may overlap the fourth channel region A4.

The third control line ELi may extend to cross the semiconductor pattern SMP. The fifth gate electrode G5 of the fifth transistor T5 and the sixth gate electrode G6 of the sixth transistor T6 may be formed by the third control line ELi. Portions of the third control line ELi overlapping the semiconductor pattern SMP may be defined as the fifth and sixth gate electrodes G5 and G6. The fifth and sixth gate electrodes G5 and G6 may overlap the fifth and sixth channel regions A5 and A6, respectively.

The fourth control line GBi may extend to cross the semiconductor pattern SMP. The seventh gate electrode G7 of the seventh transistor T7 and the eighth gate electrode G8 of the eighth transistor T8 may be formed by the fourth control line GBi. Portions of the fourth control line GBi that overlap the semiconductor pattern SMP may be defined as the seventh and eighth gate electrodes G7 and G8. The seventh and eighth gate electrodes G7 and G8 may overlap the seventh and eighth channel regions A7 and A8, respectively.

The sensing-control line GRi may extend to cross the semiconductor pattern SMP. The second gate electrode G2′ of the second transistor T2′ may be formed by the sensing-control line GRi. A portion of the sensing-control line Gri that overlaps the semiconductor pattern SMP may be defined as the second gate electrode G2′. The second gate electrode G2′ may overlap the second channel region A2′.

In drawings in the following description, for the convenience of explanation and the brief description of reference numerals, reference numerals of the source regions S1, S2, S3, S4, S5, S6, S7, and S8, the drain regions D1, D2, D3, D4, D5, D6, D7, and D8, the channel regions A1, A2, A3, A4, A5, A6, A7, and A8, and the gate electrodes G1, G2, G3, G4, G5, G6, G7, and G8 of the first to eighth transistors T1, T2, T3, T4, T5, T6, T7, and T8, and reference numerals of the source regions S1′, S2′, and S3′, the drain regions D1′, D2′, and D3′, the channel regions A1′, A2′, and A3′, and the gate electrodes G1′, G2′, and G3′ of the first to third transistors T1′, T2′, and T3′ are omitted, and the reference numerals of the first to eighth transistors T1, T2, T3, T4, T5, T6, T7, and T8 and the first to third transistors T1′, T2′, and T3′ are shown.

Referring to FIGS. 5 and 10A to 10C, a second gate pattern GPT2 may be located on the first gate pattern GPT1. The second gate pattern GPT2 may include the dummy electrode DME, a sub-dummy electrode SDE, and the bias line VBL.

The dummy electrode DME may overlap the first gate electrode G1 described above. The dummy electrode DME may form the capacitor CST together with the first gate electrode G1. An opening OP may be defined in the dummy electrode DME. A portion of the first gate electrode G1 may be exposed by the opening OP.

The sub-dummy electrode SDE may be located between the second control line Gli and the sensing-control line GRi. The sub-dummy electrode SDE may be adjacent to the fourth transistor T4. A portion of the sub-dummy electrode SDE may overlap a portion of the semiconductor pattern SMP of the fourth transistor T4.

The bias line VBL may extend in the second direction DR2, and may be located between the third control line ELi and the fourth control line GBi.

Referring to FIGS. 5 and 10A to 10D, a first connection pattern CNP1 may be located on the second gate pattern GPT2. The first connection pattern CNP1 may include a plurality of first connection electrodes CNE1, CNE1′, and CNE1-1, CNE1-2, CNE1-3, CNE1-4, CNE1-5, CNE1-6, and CNE1-7, and the second initializing line VIL2.

The first connection electrode CNE1 may be the first connection electrode CNE1 illustrated in FIG. 6. The first connection electrode CNE1′ may be the first connection electrode CNE1′ illustrated in FIG. 7. The second initializing line VIL2 may extend in the second direction DR2, and may partially overlap the sensing-control line GRi.

The first connection electrodes CNE1-1, CNE1-2, CNE1-3, CNE1-4, CNE1-5, CNE1-6, and CNE1-7 and the second initializing line VIL2 may be located at the same layer as the first connection electrodes CNE1 and CNE1′. The first connection electrodes CNE1-1, CNE1-2, CNE1-3, CNE1-4, CNE1-5, CNE1-6, and CNE1-7 and the second initializing line VIL2 may include the same material as the first connection electrodes CNE1 and CNE1′, and may be formed concurrently or substantially simultaneously with the first connection electrodes CNE1 and CNE1′ through a patterning process.

A plurality of first contact holes CH1, CH1′, and CH1-1, CH1-2, CH1-3, CH1-4, CH1-5, CH1-6, CH1-7, CH1-8, CH1-9, CH1-10, and CH1-11 may be defined. The first contact hole CH1 may be the first contact hole CH1 illustrated in FIG. 6. The first contact hole CH1′, which overlaps the first gate electrode G1′, of the first contact holes CH1′ may be the first contact hole CH1′ illustrated in FIG. 7. The first contact holes CH1-1, CH1-2, CH1-3, CH1-4, CH1-5, CH1-6, CH1-7, CH1-8, CH1-9, CH1-10, and CH1-11 may be formed in the same manner as the first contact hole CH1 or the first contact hole CH1′ illustrated in FIGS. 6 and 7.

The first connection electrode CNE1 may be connected to the sixth drain region D6 of the sixth transistor T6 through the first contact hole CH1.

The first connection electrode CNE1′ may be connected to the first gate electrode G1′ of the first transistor T1′ and the second drain region D2′ of the second transistor T2′ through the first contact holes CH1′. The first transistor T1′ and the second transistor T2′ may be connected to each other through the first connection electrode CNE1′.

The first connection electrode CNE1-1 may be connected to the dummy electrode DME of the capacitor CST and the fifth source region S5 of the fifth transistor T5 through the first contact holes CH1-1. The capacitor CST and the fifth transistor T5 may be connected to each other by the first connection electrode CNE1-1. The first connection electrode CNE1-1 may be connected to the first power line PL1 thereafter.

The first connection electrode CNE1-2 may be connected to the third drain region D3 of the third transistor T3, the fourth source region S4 of the fourth transistor T4, and the first gate electrode G1 of the first transistor T1 through the first contact holes CH1-2. The first connection electrode CNE1-2 may be connected to the first gate electrode G1 through the first contact hole CH1-2 overlapping the opening OP. The first transistor T1, the third transistor T3, and the fourth transistor T4 may be connected to each other by the first connection electrode CNE1-2.

The first connection electrode CNE1-3 may be connected to the second source region S2 of the second transistor T2 through the first contact hole CH1-3. The first connection electrode CNE1-4 may be connected to the fourth drain region D4 of the fourth transistor T4 through the first contact hole CH1-4.

The first connection electrode CNE1-5 may be connected to the fifth drain region D5 of the fifth transistor T5 and the eighth drain region D8 of the eighth transistor T8 through the first contact holes CH1-5. The fifth transistor T5 and the eighth transistor T8 may be connected to each other by the first connection electrode CNE1-6.

The first connection electrode CNE1-6 may be connected to the eighth source region S8 of the eighth transistor T8 and to the bias line VBL through first contact holes CH1-6. The eighth transistor T8 may be connected to the bias line VBL by the first connection electrode CNE1-6. Accordingly, the eighth transistor T8 may receive the bias voltage VBIAS through the bias line VBL.

The first connection electrode CNE1-7 may be connected to the third drain region D3′ of the third transistor T3′ through the first contact hole CH1-7. A connection point of the first connection electrode CNE1-7 connected to the third transistor T3′ may be defined as a first connection node CN1. In other words, the sensor circuit SNC may include the first connection node CN1.

Thereafter, the first connection electrode CNE1-7 may be connected to the receive line RXj illustrated in FIG. 10F through the second connection electrode CNE2-2 illustrated in FIG. 10E. In other words, the receive line RXj illustrated in FIG. 10F may be connected to the first connection node CN1 of the sensor circuit SNC. Accordingly, the first connection node CN1 may be defined as a connection point of the third transistor T3′ connected to the receive line RXj.

The second initializing line VIL2 may be connected to the sub-dummy electrode SDE through the first contact holes CH1-8. Accordingly, the second initializing voltage AINT may be applied to the sub-dummy electrode SDE through the second initializing line VIL2. In other words, the sub-dummy electrode SDE may receive a constant voltage.

As described above, the sub-dummy electrode SDE may overlap a portion of the semiconductor pattern SMP of the fourth transistor T4. In this case, when a constant voltage is applied to the sub-dummy electrode SDE, the threshold voltage Vth value of the fourth transistor T4 overlapping the sub-dummy electrode SDE may be maintained without changing.

The second initializing line VIL2 may be connected to the seventh drain region D7 of the seventh transistor T7 through the first contact holes CH1-9. Accordingly, the second initializing voltage AINT may be applied to the seventh transistor T7 through the second initializing line VIL2.

The second initializing line VIL2 may be connected to the second source region S2′ of the second transistor T2′ through the first contact holes CH1-10. The second initializing voltage AINT may be applied to the second transistor T2′ through the second initializing line VIL2. As described above, because the reset voltage VRST is the same voltage as the second initializing voltage AINT, the reset voltage VRST may be applied to the second transistor T2′ through the second initializing line VIL2.

The second initializing line VIL2 may be connected to the first source region S1′ of the first transistor T′ through the first contact holes CH1-11. The second initializing voltage AINT may be applied to the first transistor T1′ through the second initializing line VIL2.

A connection point of the second transistor T2′ connected to the second initializing line VIL2 may be defined as a second connection node CN2. A connection point of the first transistor T1′ connected to the second initializing line VIL2 may be defined as a third connection node CN3. In other words, the sensor circuit SNC may include the second connection node CN2 and the third connection node CN3. The second initializing line VIL2 may be connected to the second connection node CN2 and the third connection node CN3 serving as two connection nodes.

The first connection node CN1, the second connection node CN2, and the third connection node CN3 may be located between respective ones of the first control line GWi, the second control line Gli, the third control line ELi, and the sensing-control line GRi.

The first connection node CN1 may be located between the first control line GWi and the third control line ELi. The second and third connection nodes CN2 and CN3 may be located between respective ones of the first control line GWi, the second control line Gli, and the sensing-control line GRi. The second connection node CN2 may be located between the second control line Gli and the sensing-control line GRi. The third connection node CN3 may be located between the first control line GWi and the second control line Gli.

According to one or more embodiments of the present disclosure, the sensor SNP is not manufactured through a separate module, and may be embedded in the display panel DP. In this case, the sensors SN may be suitably located within a confined space. When a region for arranging the sensor circuit SNC is reduced or minimized, the resolution of the display panel DP may be increased or maximized.

According to one or more embodiments of the present disclosure, a space between the control lines GWi, Gli, ELi, and GRi may be utilized such that the first, second, and third connection nodes CN1, CN2, and CN3 may be located between respective ones of the control lines GWi, Gli, Eli, and GRi. The first, second, and third connection nodes CN1, CN2, and CN3 of the sensor circuit SNC are positioned adjacent to the pixel circuit PC and between respective ones of the control lines GWi, Gli, ELi, and GRi, such that the region for placing the sensor circuit SNC may be optimized or made more suitable. Accordingly, a region for arranging the sensor circuit SNC is reduced or minimized, such that high resolution is implemented.

Hereinafter, in FIGS. 10E and 10F, reference numerals of first connection electrodes CNE1, CNE1′, CNE1-1, CNE1-2, CNE1-3, CNE1-4, CNE1-5, CNE1-6, and CNE1-7, first contact holes CH1, CH1′, CH1-1, CH1-2, CH1-3, CH1-4, CH1-5, CH1-6, CH1-7, CH1-8, CH1-9, CH1-10, and CH1-11, the dummy electrodes DME, and the sub-dummy electrodes SDE are omitted to simplify the reference numerals.

Referring to FIGS. 5 and 10A to 10E, a second connection pattern CNP2 may be located on the first connection pattern CNP1. The second connection pattern CNP2 may include the plurality of second connection electrodes CNE2, CNE2′, CNE2-1, and CNE2-2, a sub-power line PL1′, the first initializing line VIL1, and two horizontal data lines DLH.

The second connection electrode CNE2 may be the second connection electrode CNE2 illustrated in FIG. 6. The second connection electrode CNE2′ may be the second connection electrode CNE2′ illustrated in FIG. 7. The sub-power line PL1′ may be located between the second control line Gli and the third control line ELi. The first initializing line VIL1 may extend in the second direction DR2, and may be located between the second control line Gli and the sensing-control line GRi.

The horizontal data lines DLH may extend in the second direction DR2 and may be spaced apart in the first direction DR1. The first to fourth control lines GWi, Gli, ELi, and GBi and the sensing-control line GRi may be located between the horizontal data lines DLH.

The second connection electrodes CNE2-1 and CNE2-2, the first initializing line VIL1, and the horizontal data lines DLH may be located at the same layer as the second connection electrodes CNE2 and CNE2′. The second connection electrodes CNE2-1 and CNE2-2, the first initializing line VIL1, and the horizontal data lines DLH may include the same material as the second connection electrodes CNE2 and CNE2′ and may be formed concurrently or substantially simultaneously with the second connection electrodes CNE2 and CNE2′ through a patterning process.

A plurality of second contact holes CH2, CH2′, and CH2-1, CH2-2, CH2-3, and CH2-4 may be defined. The second contact hole CH2 may be the second contact hole CH2 illustrated in FIG. 6. The second contact hole CH2′ may be the second contact hole CH2′ illustrated in FIG. 7. The second contact holes CH2-1, CH2-2, CH2-3, and CH2-4 may be formed in the same manner as the second contact holes CH2 and CH2′ illustrated in FIGS. 6 and 7.

The second connection electrode CNE2 may be connected to the first connection electrode CNE1 through the second contact hole CH2. The second connection electrode CNE2′ may be connected to the first connection electrode CNE1′ through the second contact hole CH2′.

The sub-power line PL1′ may be connected to the first connection electrode CNE1-1 through the second contact hole CH2-1. The second connection electrode CNE2-1 may be connected to the first connection electrode CNE1-3 through the second contact hole CH2-2.

The first initializing line VIL1 may be connected to the first connection electrode CNE1-4 through the second contact hole CH2-3. Accordingly, the first initializing line VIL1 may be connected to the fourth transistor T4 through the first connection electrode CNE1-4. The second connection electrode CNE2-2 may be connected to the first connection electrode CNE1-7 through the second contact hole CH2-4.

Hereinafter, for convenience of explanation, the receive line RXj and the components provided at the left side of the receive line RXj will be described with reference to FIG. 10F. In addition, in FIG. 10F, to simplify the reference numeral, the reference numerals for the second connection electrodes CNE2, CNE2′, CNE2-1, and CNE2-2 and the second contact holes CH2, CH2′, CH2-1, CH2-2, CH2-3, and CH2-4) are omitted.

Referring to FIGS. 5 and 10A to 10F, a third connection pattern CNP3 may be located on the second connection pattern CNP2. The third connection pattern CNP3 may include the plurality of third connection electrodes CNE3 and CNE3′, the first power line PL1, the data line DLj, a vertical data line DLV, and the receive line RXj.

The third connection electrode CNE3 may be the third connection electrode CNE3 illustrated in FIG. 6. The third connection electrode CNE3′ may be the third connection electrode CNE3′ illustrated in FIG. 7.

The first power line PL1, the data line DLj, the vertical data line DLV, and the receive line RXj may extend in the first direction DR1, and may be arranged in the second direction DR2. The first power line PL1 may be located between the data line DLj and the vertical data line DLV. The receive line RXj may be located at the right side of the vertical data line DLV.

The third connection electrode CNE3 may be located between the first power line PL1 and the vertical data line DLV. The third connection electrode CNE3′ may be located between the vertical data line DLV and the receive line RXj.

The first power line PL1, the data line DLj, the vertical data line DLV, and the receive line RXj may be located at the same layer as the third connection electrodes CNE3 and CNE3′. The first power line PL1, the data line DLj, the vertical data line DLV, and the receive line RXj may include the same material as the third connection electrodes CNE3 and CNE3′, and may be formed concurrently or substantially simultaneously with the third connection electrodes CNE3 and CNE3′ through a patterning process.

A plurality of third contact holes CH3, CH3′, CH3-1, CH3-2, and CH3-3 may be defined. The third contact hole CH3 may be the third contact hole CH3 illustrated in FIG. 6. The third contact hole CH3′ may be the third contact hole CH3′ illustrated in FIG. 7. The third contact holes CH3-1, CH3-2, and CH3-3 may be formed in the same manner as the third contact holes CH3 and CH3′ illustrated in FIGS. 6 and 7.

The third connection electrode CNE3 may be connected to the second connection electrode CNE2 through the third contact hole CH3. In one or more embodiments, the third connection electrode CNE3 may be connected to the first electrode AE as described in FIG. 6. Therefore, the first electrode AE may be connected to the sixth transistor T6 through the first connection electrode CNE1, the second connection electrode CNE2, and the third connection electrode CNE3 illustrated in FIGS. 10D, 10E, and 10F.

The third connection electrode CNE3′ may be connected to the second connection electrode CNE2′ through the third contact hole CH3′. In one or more embodiments, the third connection electrode CNE3′ may be connected to the first electrode AE′ as described in FIG. 7. Therefore, the first electrode AE′ may be connected to the first transistor T1′ through the first connection electrode CNE1′, the second connection electrode CNE2′, and the third connection electrode CNE3′ illustrated in FIGS. 10D, 10E, and 10F.

The first power line PL1 may be connected to the sub-power line PL1′ through the third contact hole CH3-1. Accordingly, the first power line PL1 may be connected to the dummy electrode DME of the capacitor CST through the sub-power line PL1′ and the first connection electrode CNE1-1.

The data line DLj may be connected to the second connection electrode CNE2-1 through the third contact hole CH3-2. Accordingly, the data line DLj may be connected to the second transistor T2 through the second connection electrode CNE2-1 and the first connection electrode CNE1-3.

The receive line RXj may be connected to the second connection electrode CNE2-2 through the third contact hole CH3-3. Accordingly, the receive line RXj may be connected to the third transistor T3′ through the second connection electrode CNE2-2 and the first connection electrode CNE1-7.

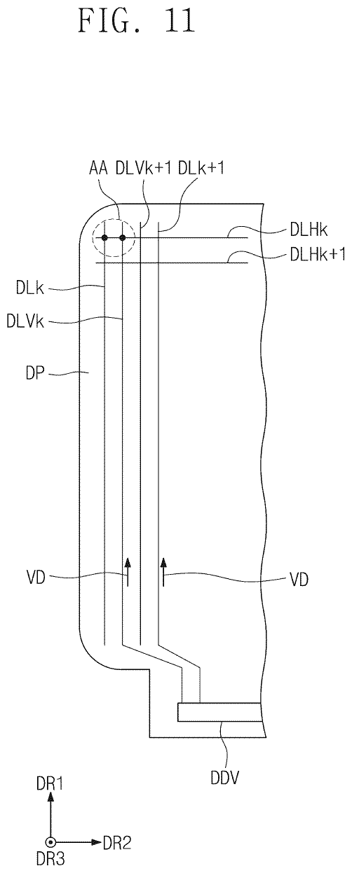

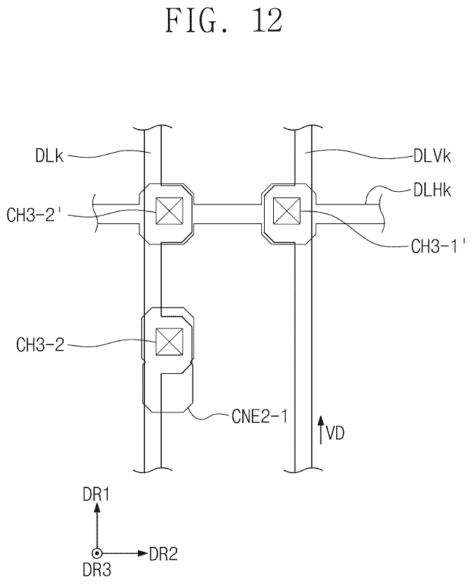

In FIGS. 10E and 10F, the horizontal and vertical data lines DLH and DLV may not be connected to other lines. Functions of the horizontal and vertical data lines DLH and DLV illustrated in FIGS. 10E and 10F will be described with reference to FIGS. 11 and 12.

FIG. 11 is a view illustrating an edge of the display panel illustrated in FIG. 4 in more detail. FIG. 12 is an enlarged view of region AA illustrated in FIG. 11 to describe the functions of horizontal and vertical data lines illustrated in FIGS. 10E and 10F.

For example, a left portion of the display panel DP is illustrated in FIG. 11.

Referring to FIGS. 4 and 11, the display panel DP may further include a plurality of horizontal data lines DLHk and DLHk+1 and a plurality of vertical data lines DLVk and DLVk+1. The horizontal data lines DLHk and DLHk+1 may extend in the second direction DR2, and may be arranged in the first direction DR1. The vertical data lines DLVk and DLVk+1 may extend in the first direction DR1, and may be arranged in the second direction DR2.

For example, although FIG. 11 illustrates that two data lines DLk and DLk+1, two horizontal data lines DLHk and DLHk+1, and two vertical data lines DLVk and DLVk+1, many additional lines may be located on the display panel DP.

Substantially, the corner of the display panel DP may have a round shape. In addition, the width of the display panel DP in which the data driver DDV is placed in the second direction DR2 may be smaller than the width of the display panel DP in which the pixels PX are placed in the second direction DR2.

It may be difficult to directly connect the k-th data line DLk, which is located at an outer portion while being adjacent to the rounded-shape corner, to the data driver DDV, due to the shape of the display panel DP. Accordingly, the k-th data line DLk may be connected to the data driver DDV using the k-th horizontal data line DLHk and the k-th vertical data line DLVk.

Referring to FIGS. 11 and 12, the k-th data line DLk may be connected to the data driver DDV through the k-th horizontal data line DLHk and the k-th vertical data line DLVk. The k-th vertical data line DLVk may be connected to the data driver DDV to receive the data voltage VD. In this case, ‘k’ may be a natural number.

For example, FIG. 12 illustrates the k-th data line DLk, the second connected electrode CNE2-1 connected to the k-th data line DLk, the k-th horizontal data line DLHk connected to the k-th data line DLk, and a k-th vertical data line DLVk connected to the k-th data line DLk.

The k-th data line DLk may be connected to the second connection electrode CNE2-1 through the third contact hole CH3-2 as described in FIG. 10F. The k-th vertical data line DLVk may be connected to the k-th horizontal data line DLHk through the third contact hole CH3-1′. The k-th horizontal data line DLHk may be connected to the k-th data line DLk through the third contact hole CH3-2′.

The data voltage VD may be provided to the k-th data line DLk through the k-th vertical data line DLVk and the k-th horizontal data line DLHk.

The (k+1)-th data line DLk+1 may be connected to the data driver DDV, and the (k+1)-th vertical data line DLVk+1 may not be connected to the data driver DDV. The (k+1)-th horizontal data line DLHk+1 may not be connected to the (k+1)-th data line DLk+1 and the (k+1)-th vertical data line DLVk+1.

The k-th horizontal data line DLHk and the k-th vertical data line DLVk may be used to connect the k-th data line DLk located at the outer portion while being adjacent to the corner of the round shape to the data driver DDV.

The data lines DLj and horizontal and vertical data lines DLH and DLV illustrated in FIGS. 10E and 10F may correspond to the (k+1)-th data line DLk+1, the (k+1)-th horizontal data line DLHk+1, and the (k+1)-th vertical data line DLVk+1.

According to one or more embodiments of the present disclosure, the connection nodes of the sensor circuit connected to the receive line and the second initializing line are adjacent to the pixel circuit, and are located between the control lines, thereby optimizing or improving the region for the sensor circuit. Accordingly, the region for the sensor circuit may be reduced or minimized such that the higher resolution is implemented.

Although one or more embodiments of the present disclosure has been described for illustrative purposes, those skilled in the art will appreciate that various modifications, and substitutions are possible, without departing from the scope and spirit of the invention as disclosed in the accompanying claims. Further, while the present disclosure has been described with reference to embodiments thereof, it will be apparent to those of ordinary skill in the art that various changes and modifications may be made thereto without departing from the spirit and scope of the present disclosure as set forth in the following claims, with functional equivalents thereof to be included therein.

What is claimed is:

1. A display device comprising:
a first control line, a second control line, and a third control line arranged in a first direction, the first control line being between the second control line and the third control line;
a pixel circuit coupled to the first control line, the second control line, and the third control line;
a light-emitting element coupled to the pixel circuit;
a sensor circuit coupled to the first control line, and having a first connection node between the first control line and the third control line;
a light-receiving element coupled to the sensor circuit; and
a receive line coupled to the first connection node of the sensor circuit.

2. The display device of claim 1, further comprising:
a data line coupled to the pixel circuit;
a first initializing line coupled to the pixel circuit; and
a second initializing line coupled to the pixel circuit and the sensor circuit,
wherein the second initializing line is coupled to a second connection node and a third connection node of the sensor circuit.

3. The display device of claim 2, further comprising a sensing-control line coupled to the sensor circuit,
wherein the second control line is between the first control line and the sensing-control line.

4. The display device of claim 3, wherein the second connection node is between the second control line and the sensing-control line.

5. The display device of claim 1, wherein the third connection node is between the first control line and the second control line.

6. The display device of claim 3, wherein the sensor circuit comprises:
a first transistor comprising a first electrode coupled to the second initializing line, a control electrode coupled to an anode of the light-receiving element, and a second electrode;
a second transistor comprising a first electrode coupled to the second initializing line, a control electrode coupled to the sensing-control line, and a second electrode coupled to the anode; and
a third transistor comprising a first electrode coupled to the second electrode of the first transistor, a control electrode coupled to the first control line, and a second electrode coupled to the receive line.

7. The display device of claim 6, wherein the first connection node is defined as a connection point of the third transistor coupled to the receive line.

8. The display device of claim 6, wherein the second connection node is defined as a connection point of the second transistor coupled to the second initializing line.

9. The display device of claim 6, wherein the third connection node is defined as a connection point of the first transistor coupled to the second initializing line.

10. The display device of claim 6, wherein the second transistor has a dual-gate structure, and wherein the third transistor has a dual-gate structure.

11. The display device of claim 1, wherein the first transistor, the second transistor, and the third transistor comprise PMOS transistors.

12. The display device of claim 2, wherein the pixel circuit comprises:
a first transistor comprising a first electrode coupled to a first power line, a second electrode coupled to an anode of the light-emitting element, and a control electrode coupled to a node;
a second transistor comprising a first electrode coupled to the data line, a second electrode coupled to the first electrode of the first transistor, and a control electrode coupled to the first control line; and
a capacitor comprising a first electrode coupled to the first power line, and a second electrode coupled to the node.

13. The display device of claim 12, wherein the pixel circuit comprises:
a third transistor comprising a first electrode coupled to the second electrode of the first transistor, a second electrode coupled to the node, a control electrode coupled to the first control line; and
a fourth transistor comprising a first electrode coupled to the node, a second electrode coupled to the first initializing line, and a control electrode coupled to the second control line.

14. The display device of claim 13, wherein the third transistor has a dual gate structure, and wherein the fourth transistor has a dual-gate structure.

15. The display device of claim 13, wherein the pixel circuit comprises:
a fifth transistor comprising a first electrode coupled to the first power line, a second electrode coupled to the first electrode of the first transistor, and a control electrode coupled to the third control line; and
a sixth transistor comprising a first electrode coupled to the second electrode of the first transistor, a second electrode coupled to the anode, and a control electrode coupled to the third control line.

16. The display device of claim 15, further comprising:
a fourth control line; and
a bias line,
wherein the pixel circuit comprises:
a seventh transistor comprising a first electrode coupled to the anode, a second electrode coupled to the second initializing line, and a control electrode coupled to the fourth control line; and
an eighth transistor comprising a first electrode coupled to the bias line, a second electrode coupled to the first electrode of the first transistor, and a control electrode coupled to the fourth control line.

17. The display device of claim 16, wherein the third control line is between the first control line and the fourth control line.

18. The display device of claim 16, wherein the first to eighth transistors comprise PMOS transistors.

19. A display device comprising:
a first control line, a second control line, a third control line, and a sensing-control line arranged in a first direction;
a pixel circuit coupled to the first control line, the second control line, and the third control line;
a light-emitting element coupled to the pixel circuit;
a sensor circuit coupled to the first control line and the sensing-control line;
a light-receiving element coupled to the sensor circuit;
a receive line coupled to a first connection node of the sensor circuit;
a first initializing line coupled to the pixel circuit; and
a second initializing line coupled to the pixel circuit, and to a second connection node and to a third connection node of the sensor circuit,
wherein the first connection node, the second connection node, and the third connection node are between respective ones of the first control line, the second control line, the third control line, and the sensing-control line.

20. A display device comprising:
a first control line, a second control line, and a sensing-control line arranged in a first direction;
a pixel circuit coupled to the first control line and the second control line;
a light-emitting element coupled to the pixel circuit;
a sensor circuit coupled to the first control line and the sensing-control line;
a light-receiving element coupled to the sensor circuit; and
a first initializing line coupled to the pixel circuit; and
a second initializing line coupled to the pixel circuit, and to two connection nodes of the sensor circuit that are respectively between the first control line, the second control line, and the sensing-control line.
